(19) United States
(12) Patent Application Publication
(10) Pub. No.: US 2026/0222713 A1
(43) Pub. Date: Jul. 30, 2026

(54) SWITCHING SYSTEMS CONFIGURED TO RECEIVE OPTICAL AND ELECTRICAL MODULES

(71) Applicant: Eridu Al Corporation, Saratoga, CA (US)

(72) Inventors: Christopher Robert Cole, Saratoga, CA (US); Frank Yang, Saratoga, CA (US)

(21) Appl. No.: 19/038,401

(22) Filed: Jan. 27, 2025

(51) Int. Cl. H04Q 11/00; H05K 7/20

(52) U.S. Cl. CPC H04Q 11/0005; H05K 7/20254; H05K 7/20836; H04Q 2011/0039; H04Q 2011/0041; H04Q 2011/0058

(57) ABSTRACT

An apparatus, such as a switch, is provided that comprises, in one example, a housing with vertically oriented first and second cards, both of which are referred to herein as mezzanine or daughter cards. In one example, the first and second mezzanine cards are positioned adjacent to the front side of the housing and are provided in sub-assembly enclosures. The first mezzanine cards are configured to connect to interface modules capable of receiving and transmitting optical signals or electrical signals. A second card, referred to herein as a host or line card, also vertically extends within the housing and includes a processor package with a processor, such as a switch ASIC, for processing or switching data associated with the optical signals. The system employs connectors and cables that couple the first mezzanine cards to the second mezzanine card. Further, additional connectors are used to couple the second mezzanine cards to the line card and ASIC. In addition, a plurality of heat transfer elements, such as cold plates or air-cooled heat sinks, facilitate thermal management of the interface modules. In a further example, the second mezzanine cards are oriented horizontally and are thus provided parallel to the bottom of the housing, whereas, in one example, vertically oriented cards are positioned orthogonally to the bottom of the housing. In a further example, one vertical mezzanine card is provided adjacent to the vertical line card and cables, as well as connectors, connect the vertical mezzanine card to the interface modules without an intervening mezzanine card.

### BACKGROUND

The document describes switching systems configured to receive optical and electrical modules.

### SUMMARY

An apparatus, such as a switch, is provided that comprises, in one example, a housing with vertically oriented first and second cards, both of which are referred to herein as mezzanine or daughter cards. In one example, the first and second mezzanine cards are positioned adjacent to the front side of the housing and are provided in sub-assembly enclosures. The first mezzanine cards are configured to connect to interface modules capable of receiving and transmitting optical signals or electrical signals. A second card, referred to herein as a host or line card, also vertically extends within the housing and includes a processor package with a processor, such as a switch ASIC, for processing or switching data associated with the optical signals. The system employs connectors and cables that couple the first mezzanine cards to the second mezzanine card. Further, additional connectors are used to couple the second mezzanine cards to the line card and ASIC. In addition, a plurality of heat transfer elements, such as cold plates or air-cooled heat sinks, facilitate thermal management of the interface modules. In a further example, the second mezzanine cards are oriented horizontally and are thus provided parallel to the bottom of the housing, whereas, in one example, vertically oriented cards are positioned orthogonally to the bottom of the housing. In further additional example, one vertical mezzanine card is provided adjacent to the vertical line card and cables, as well as connectors, connect the vertical mezzanine card to the interface modules without an intervening mezzanine card.

Each pair of first and second mezzanine cards and associated cables and connectors are self-contained within a corresponding sub-assembly enclosure. Accordingly, replacing a faulty or defective cable and/or mezzanine card may be readily accomplished by replacing a corresponding sub-assembly enclosure rather than disabling the entire switch to access the defective component.

### BRIEF DESCRIPTION OF THE DRAWINGS

FIG. 1 depicts an exemplary system configured for data processing and optical and/or electrical communication within a data center environment, accordance with some embodiments of the present disclosure;

FIG. 2A shows a simplified perspective view of a switch consistent with an aspect of the present disclosure;

FIG. 2B shows a high-level perspective view of internal components of the switch shown in FIG. 2A consistent with a further aspect of the present disclosure;

FIG. 2C shows a perspective view of a sub-assembly enclosure consistent with an aspect of the present disclosure;

FIGS. 3A and 3B show front views of a switch consistent with additional aspects of the present disclosure;

FIG. 4 shows a cross-sectional or side view of internal components of the switch shown in FIGS. 3A or 3B;

FIG. 5 shows a front view of a switch consistent with a further aspect of the present disclosure; and

FIGS. 6A and 6B show cross-sectional or side views of example arrangements of internal components of the switch shown in FIG. 5.

FIGS. 7 and 8 show additional cross-sectional or side views of example arrangements of internal components of the switch shown in FIG. 5.

### DETAILED DESCRIPTION

The following detailed description of example implementations refers to the accompanying drawings. The same reference numbers in different drawings may identify the same or similar elements.

Communication networks, such as those provided in data centers often include switches for directing data between various processing units, such as CPUs, GPUs, and further interconnected switches. These switches often include optical or electrical transceiver modules and electrical processing components, such as a switch application specific integrated circuit (ASIC) provided in a chassis. As increasing numbers of processing units are provided in a data center, for example, higher capacity switches may be required that can accommodate a large number of transceiver modules. However, such switches require greater connectivity, higher component density, and thermal management. Moreover, manufacturing or assembling high-capacity switches, as well as repairing or sparing components in such switches, may be difficult in light of such requirements.

As noted above and described in greater detail below, pairs of first and second mezzanine cards are housed in sub-assembly enclosure. The first mezzanine card of each pair is provided adjacent to the front of the chassis or housing and is coupled to interface or transceiver modules. Moreover, the second mezzanine card of each pair is connected to the first mezzanine card by cables and connectors on one side and connected by way of connectors to the line card and the ASIC provided thereon on the other side. Both the first and second mezzanine cards are provided in a sub-assembly enclosure that is easily disconnected from the line card. As a result, if a mezzanine card becomes defective or a cable connecting a pair of first and second mezzanine cards breaks, a user need only remove the sub-assembly enclosure including the defective card and/or broken cable, for example, instead of disabling the entire switch to remove the defective parts.

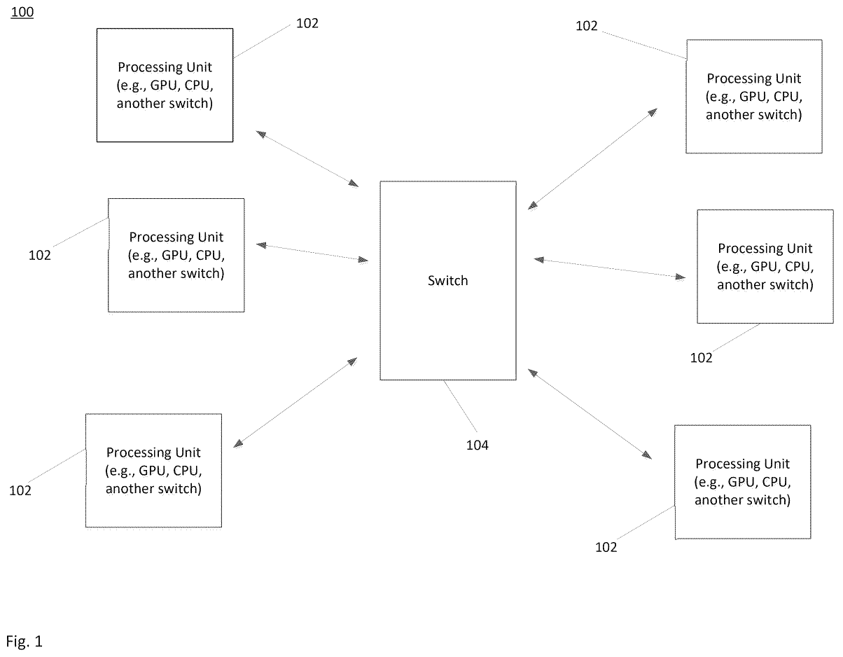

Turning to the drawings, FIG. 1 depicts a system 100 configured for data processing and optical and/or electrical communication within a data center environment, for example. The system 100 comprises a plurality of processing units 102 interconnected to a switch 104 consistent with the present disclosure. Each processing unit 102 may include a graphics processing unit (GPU), a central processing unit (CPU), or alternatively operate as another switch. In the illustrated architecture, switch 104 is operable to receive data transmissions from one or more of the processing units 102 and to direct this data accordingly to one or more of the other processing units 102.

FIG. 1 is provided as an example of a system. Other examples may differ from what is described with regard to FIG. 1. The number and arrangement of components shown in FIG. 1 are provided as an example. In practice, there may be additional components, fewer components, different components, or differently arranged components than those shown in FIG. 1.

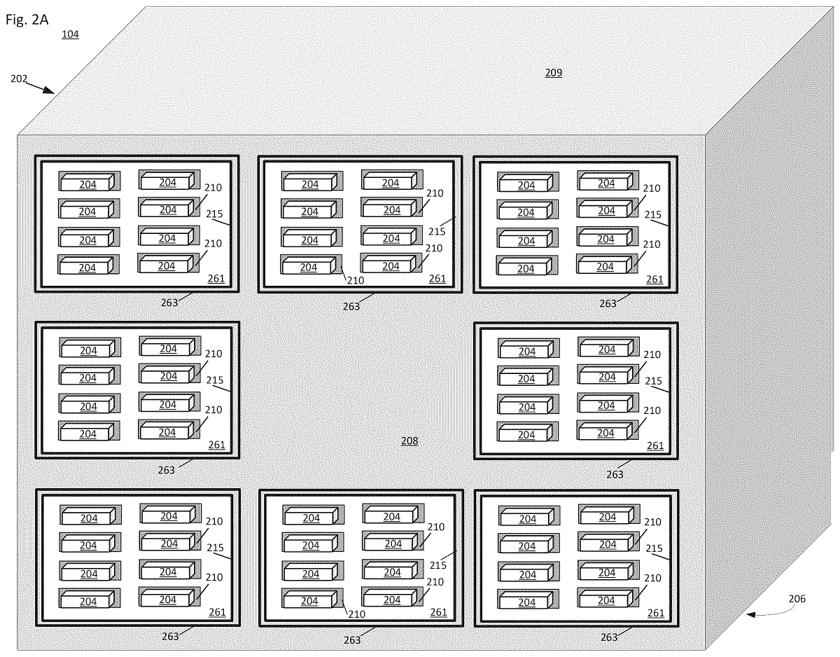

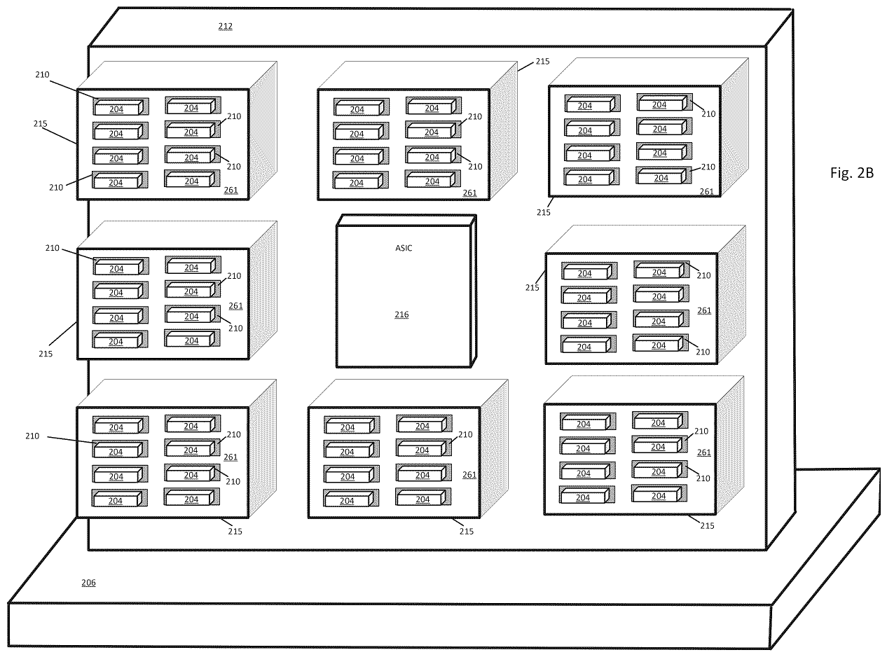

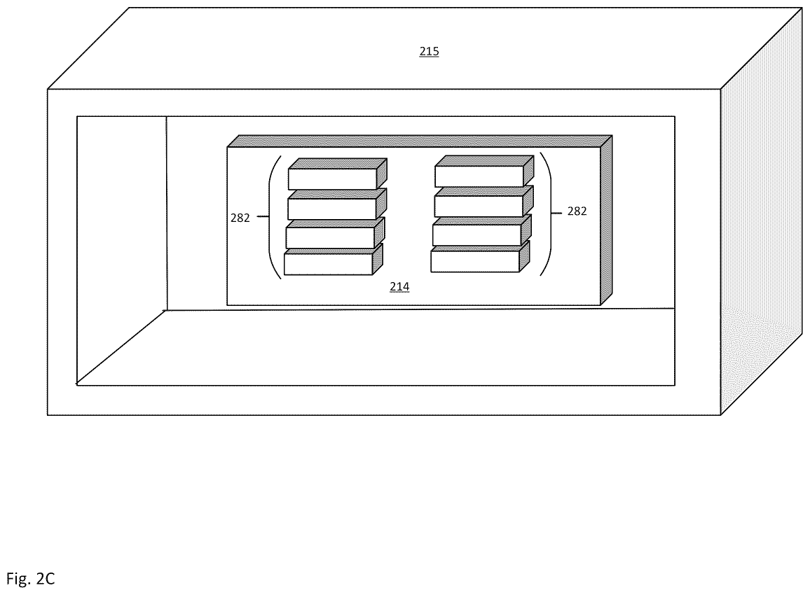

FIG. 2A shows switch 104 in greater detail. As shown in FIG. 2A, switch 104 includes a housing or chassis 202 that comprises a bottom 206 and a top 209. The housing 202 additionally features a front panel 208 which includes a plurality of module slots or ports 210.

Each module slot 210 is configured to receive a corresponding optical or electrical module or interface module 204, which in one example is a transceiver module. These modules or interface modules 204 facilitate communication between switch 104 and processing units 102 (not shown in this figure). Modules 204 supporting optical communication are operable to convert input optical signals into input electrical signals for processing or switching, and by converting processed or switched electrical signals into output optical signals. Each module may be a pluggable module, such as a module complying with an OSFP standard or OSFP module.

Put another way, modules 204 may be embodied as transceiver modules, capable of both outputting optical signals carrying data to at least one of the processing units 102 and receiving optical signals carrying data from at least one of the processing units 102. In this particular embodiment, modules 204 are shown as being provided in module slots 210 in faceplate 261 of sub-assembly enclosure 215. Sub-assembly enclosure 215, in turn, may be provided in openings 263 of chassis or housing front panel 208. In a further example, modules 204 may be transceiver modules that output or transmit first electrical signals as well as receive second electrical signals.

The housing 202 is designed with structural features to support the integration of modules 204, ensuring their alignment and secure attachment within the module slots 210 and providing protection for internal components. Although not specifically illustrated in FIG. 2A, the housing 202 may contain additional components, such as data processors and circuits, which interact with modules 204 to perform necessary communication and signal conversion functions.

As indicated above, FIG. 2A is provided as an example. Other examples may differ from what is described with regard to FIG. 2A.

FIG. 2B shows a simplified perspective view of components provided within switch 104. Namely, FIG. 2B shows a vertical host card 212, also referred to as a vertical line card, designed to operate within the switch 104.

The vertical host card 212 supports a processor, such as an application-specific integrated circuit (ASIC) 216, mounted on card 212 and facing front panel 208 of the chassis 202. The ASIC 216 may provide specialized processing operations, such as switching, required for routing or directing data through switch 104. While FIG. 2B illustrates the ASIC 216 positioned on the side of the vertical host card 212 that faces the front panel 208, it is contemplated that the ASIC 216 could alternatively be positioned on the reverse side, facing away from the front panel 208 towards the back of the chassis 202.

In the arrangement shown in FIG. 2B, multiple sub-assembly enclosures 215 are connected or attached to vertical line card 212. As discussed in greater detail below, each sub-assembly enclosure 215 includes two vertical mezzanine cards and associated cables and connectors (not shown in FIG. 2B for ease of illustration). In addition, each sub-assembly enclosure is detachable from vertical line card 212 independently of the other sub-assembly enclosures 215. As a result, in the event one of the sub-assembly enclosures 215 includes a faulty component, such as a defective mezzanine card or broken or faulty cable, only that sub-assembly enclosure 215 may be readily detached from line card 212 while the remaining sub-assembly enclosures remain in place and operational. Accordingly, defective components may be readily replaced or repaired by only removing the corresponding sub-assembly enclosure.

As further shown in FIG. 2B, the bottom of the housing 206 provides a structural base for securely positioning the vertical host card 212 and the associated components within housing 202. The arrangement of vertical host card 212, ASIC 216 mounted thereon, and sub-assembly enclosures 215 with interface modules 204 represents an example configuration that facilitates effective communication between the modules 204 and the processing unit within the switch via ASIC 216.

Alternate configurations with varying numbers and arrangements of mezzanine cards, host cards, connectors, and modules are also considered to fall within the scope of the present disclosure.

FIG. 2B is provided as an example. Other examples may differ from what is described with regard to FIG. 2B. The number and arrangement of components shown in FIG. 2B are provided as an example. In practice, there may be additional components, fewer components, different components, or differently arranged components than those shown in FIG. 2B.

FIG. 2C shows a simplified perspective view of sub-assembly enclosure 215. For ease of explanation, faceplate 261 is not shown in FIG. 2C. As shown in FIG. 2C, sub-assembly enclosure includes, in one example, a vertical mezzanine card 214 and a plurality of connectors 218 provided on card 214. Each of connectors 282 is operable to receive a respective interface module 204. In one example, each module 204 plugs into a corresponding connector 282.

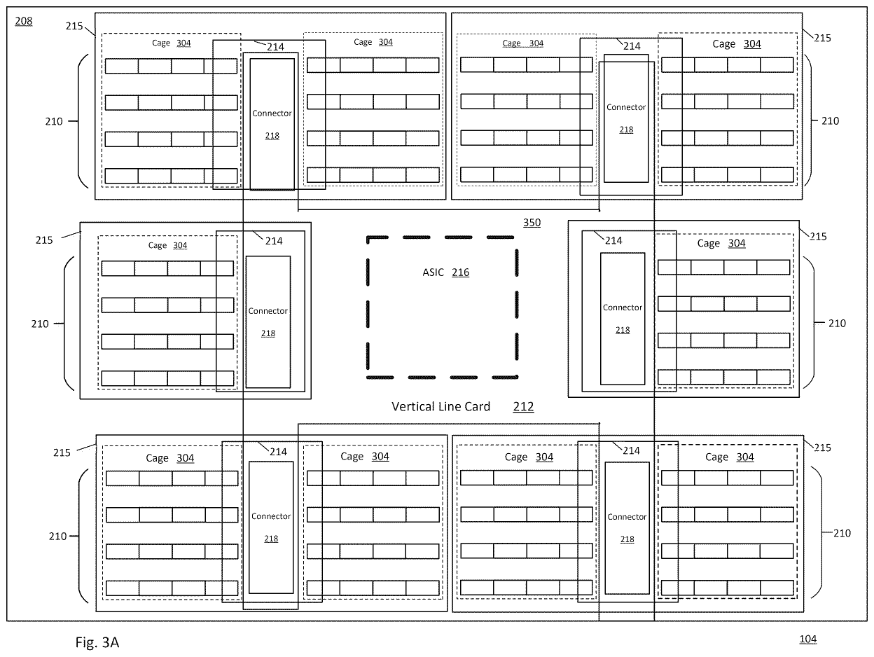

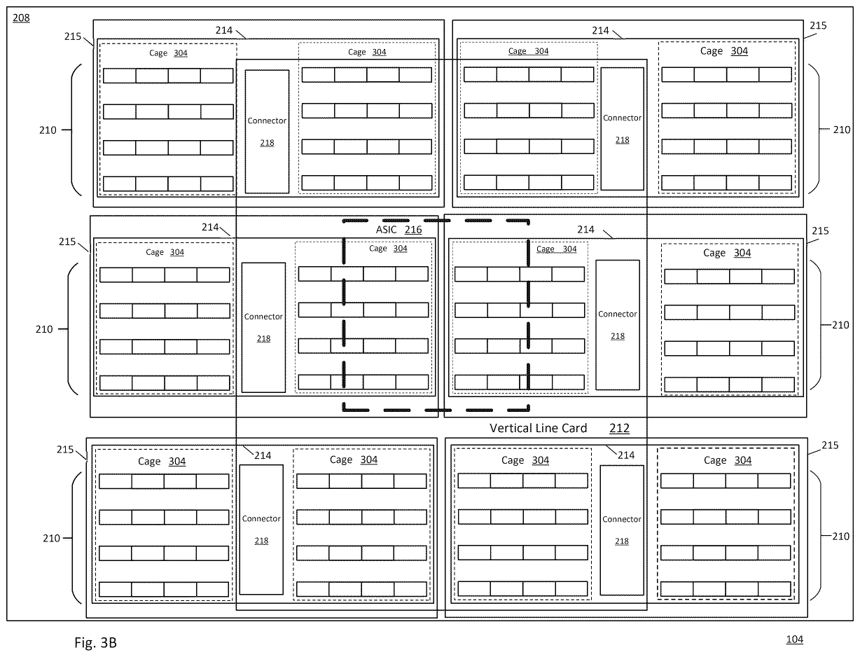

FIG. 3A shows a front view of switch 104 consistent with a further aspect of the present disclosure. As shown in FIG. 3A, switch 104 includes vertical mezzanine cards 214, which are arranged to define a gap or space 350 that defines a region on the vertical line card 212 including the switch ASIC 216. Vertical mezzanine cards 214 connect to a plurality of optical or electrical modules 204 by way of cables and each mezzanine card includes at least one connector 218 for interfacing with vertical line card 212. In one example, the front panel 208 of the switch 104 includes slots 210 in faceplates 261 (not shown in FIG. 3A) of sub-assembly enclosures 215 for receiving each module 204. Further, one or more additional integrated circuits may be provided on card 212.

As further shown in FIG. 3A, the configuration of vertical mezzanine cards 214 is such that peripheral portions of these cards do not overlap with the switch ASIC 216 on the vertical line card 212 when viewed from the front of chassis 202. As a result, ASIC 216 may be more readily accessed. Moreover, greater airflow may be directed over ASIC 216 to facilitate more efficient cooling. Accordingly, as shown in FIG. 3A, gap 350 is shown over ASIC 216.

Additionally, the arrangement of the mezzanine cards 214 in FIG. 3 shows cages 304, which serve to protect and organize the optical or electrical modules 204. Cages 304 are typically constructed to provide a stable structure for module insertion and retention, as well as aiding in thermal management and electromagnetic interference (EMI) shielding.

Preferably, vertical mezzanine card 214, connector 218, and cage 304 are provided in sub-assembly enclosure 215. In addition to the advantages noted above in providing a modular assembly based on such sub-assembly enclosures, it is noted that, in one example, the sub-assembly enclosures may be manufactured separately from line card 212 and associated components and readily plugged into connectors attached to the line card to complete the switch 104.

Optical modules 204 may include optical transceiver modules compliant with an OSFP standard. The modules or interface modules may be pluggable, such as into a connector as described below. In a further example, 160 modules are provided, each with a capacity of 800 Gb/s to thereby support a total interconnect bandwidth of 128 Tb/s. Other numbers of module slots 210 and modules, as well as module bandwidths result in different interconnect bandwidths. The optical modules 204 are grouped in 4×4 two-dimensional array in cages 304, in the example shown in FIG. 3A. Other cage groupings and other cage array sizes, such as 8×4 two-dimensional array are contemplated herein. Moreover, the example shown in FIG. 3A includes six vertical mezzanine cards (also referred to herein as “VMCs”) 214 on which the optical modules 204 are mounted in a similar manner to the mounting of optical modules on a vertical line card (also referred to herein as “VLC”), although, further consistent with the present disclosure, more or fewer vertical mezzanine cards may be provided. In the example shown in FIG. 3A, only ASIC 216 is provided on vertical line card (VLC) 212 and other support circuitry are located, but no optical modules.

Vertical line card 212 and vertical mezzanine card 214 can include printed circuit boards (PCBs), organic substrates or other material types used for assembling and interconnecting electrical components, such as ASICs. It is understood that a greater or lower number of module slots other than that shown in FIG. 3A can be supported.

As indicated above, FIG. 3A is provided as an example. Other examples may differ from what is described with regard to FIG. 3A. The number and arrangement of components shown in FIG. 3A are provided as an example. In practice, there may be additional components, fewer components, different components, or differently arranged components than those shown in FIG. 3A.

FIG. 3B shows a front view of another example of switch 102. Here, selected mezzanine cards 214, cages 304, and sub-assembly enclosures 215 are shown overlapping with ASIC 216 when viewed from the front of housing 202.

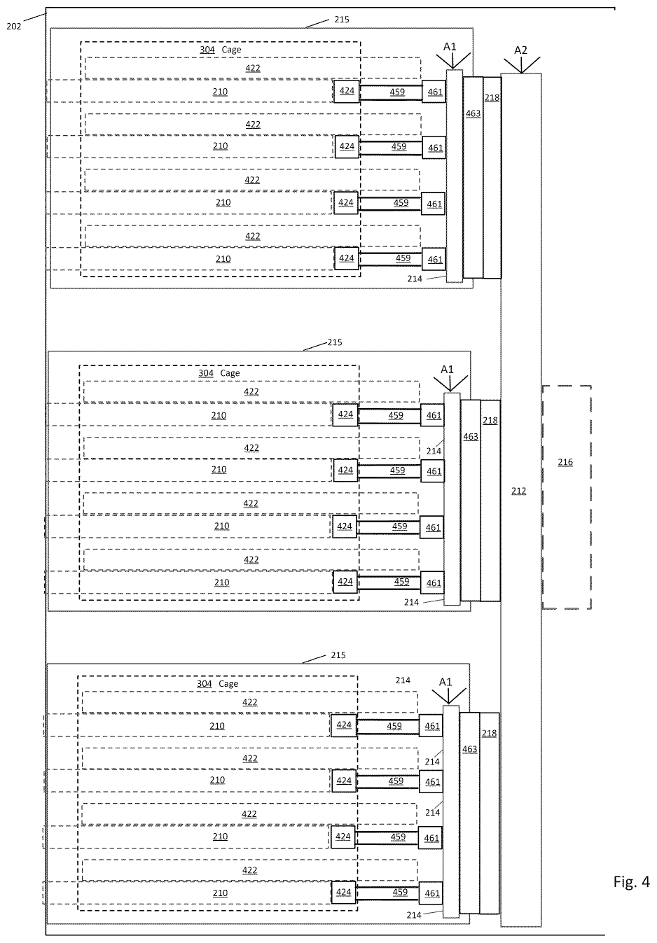

FIG. 4 shows a cross-sectional view of internal components of switch 104 shown in FIG. 3A or 3B. In particular, the example shown in FIG. 4 includes an arrangement of vertical mezzanine cards (VMCs) 214 in proximity to a vertical line card (VLC) 212 for optimizing signal integrity and thermal management in switch 104.

As noted above, vertical mezzanine cards 214 each house a plurality of optical or electrical modules contained within module slots or ports 210. These modules, though not explicitly labeled, are understood to be housed within each VMC 214.

FIG. 4 shows a connection between ASIC 216 and module slots 210 using both cable and printed circuit boards (PCB). Other materials are contemplated herein. In the example shown in FIG. 4, ASIC 216 is provided on one side of vertical line card 212 and a two-piece connector including connectors 218 and 463 is provided on the opposite side of line card 212.

Conductors included or embedded in vertical line card 212 electrically connect ASIC 216 to connector 218. Thus, electrical signals output from ASIC 216 are provided to the two-piece connector and next fed to vertical mezzanine card 214. Additional traces or conductors in card 214 further carry the electrical signal to connector provided on a side of mezzanine card 214 opposite connector 463. Connector 461, in turn, is connected to cables 459, which supply the electrical signals to a further connector 424, which, in one example, is a receptacle connector operable to receive and electrically connect to an interface module 204 when such module is plugged into slot 210.

It is noted that, instead of a two-piece connector, other connectors including, interposers, for example, may be provided. As noted above, vertical mezzanine card 2143 has a cable connection which connects to the cable connection 424 in module slot 210, which, in turn, connects to module 204 when such module is plugged into module slot 210. In one example, cables 459 carry high speed signals from ASIC 216, as well as power and control signals from the vertical mezzanine card 214. FIG. 4 shows a side view of the example switch configurations shown in both FIGS. 3A and 3B.

In addition, heat transfer elements 422, which may include one of a cold plate, an air-cooled heat sink, or a liquid cooled cold plate are provided to remove heat from modules 204 when such modules are provided in module cages 304. Further, as noted above, receptacle connector 424 may be provided to receive and provide an electrical connection to each module when inserted into a slot 210.

Returning to FIG. 3A, vertical mezzanine cards 214 and vertical line card VLC 212 are located relatively close to one another so that a low-profile two-piece connector including connectors 218 and 463 connects these two cards. As a result, a relatively high signal integrity may be obtained. However, in order to provide vertical mezzanine cards 214 in close proximity to vertical line card 212, preferably no vertical line card or portion of a vertical line card is located in front of ASIC 216 to thereby prevent interference. In FIGS. 3 and 4, each VMC 214 is shown mounting one connector 218. However, the connection between these cards may be realized with multiple smaller size connectors also referred to as a connector field. As noted above, modules 204 may be cooled by heat transfer elements, such as heat sinks or cold plates. If heat sinks are provided, air flow is preferably directed over the heat sinks. As a result, heat generated by modules 204, when such modules are provided in cages 304, and absorbed by the heat sinks is dissipated by the air flow, thereby cooling the heat sinks. Preferably, the heat sinks are mounted to the top of and are thus in contact with modules 204, and the air flow is through holes in vertical line cards 214, similar to through holes which may be provided in vertical line card 212. Modules 204 can also be cooled by a cold plate, which can also extend through holes in the vertical mezzanine card 214 with heat extracted behind such card by way of a liquid coolant, for example.

As noted above, housing 202 includes, among other things, vertical mezzanine cards or daughter cards 214 and a vertical host or line card 212. In one example, each of the plurality of vertical mezzanine cards 214 is oriented at a first angle Al relative to the front panel 208, the first angle is in a range from −60° to 60°. In addition, vertical line card 212 may be oriented at a second angle A2 in a range from −60° to 60° relative to front panel 208, as also shown in FIG. 4. In a further example, both first angle Al and second angle A2 are both 0°, such that each card 214 and card 212 are parallel to front panel 208. Angles A1 and A2 may be the same or different, consistent with the present disclosure. Line card and mezzanine cards discussed below may also be oriented within a range of −60° to 60° relative to front panel 208 in a manner similar to that discussed above in connection with FIG. 4.

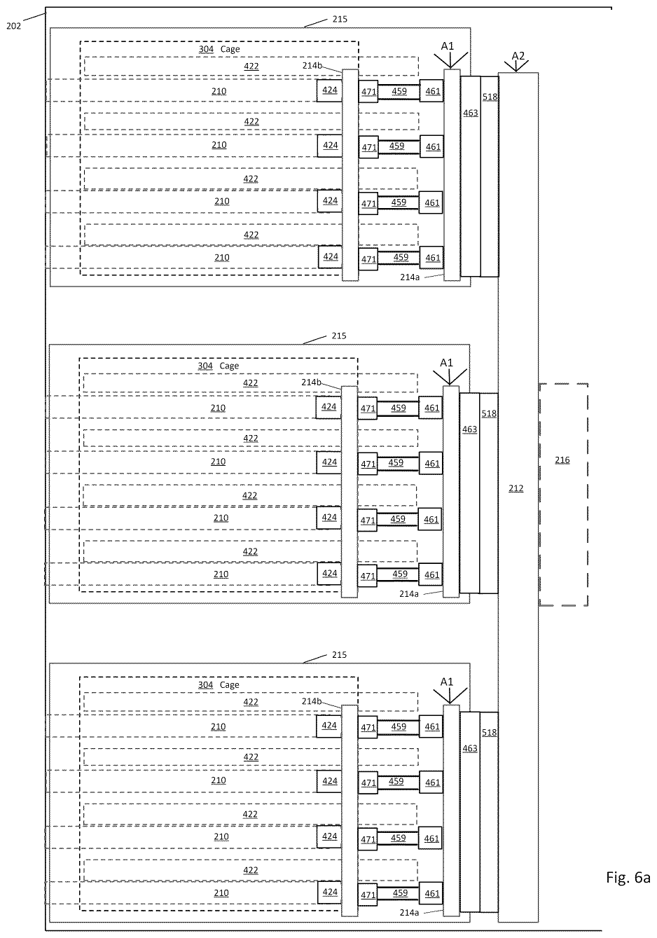

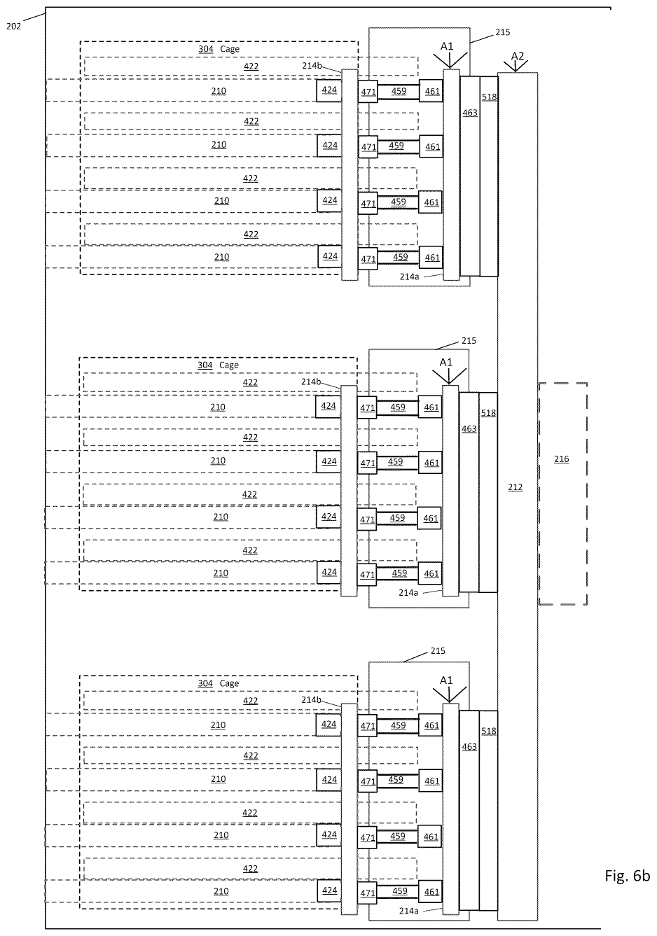

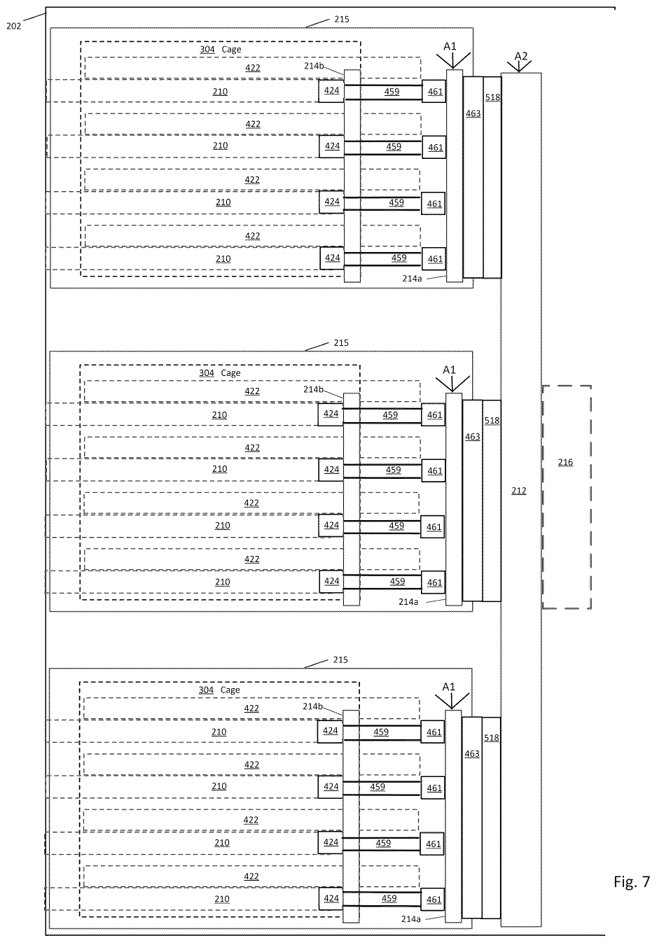

In one example, an electrical connections may be provided between connectors 424 and line card 212. Each such connection may include a corresponding one of connectors 424, cable bundles 459, connectors 461, conductors in extending through mezzanine card 214, connector 463, and connector 218. As discussed in greater detail below, the electrical connection may further include a corresponding one of connectors 471 (FIGS. 6a and 6b) connecting connectors 424 to cable bundles 459, conductors extending through mezzanine cards 214b (FIG. 7) connecting connectors 424 to cable bundles 459, and conductors provided on horizontal mezzanine cards 214c connecting connectors 424 to cable bundles 459. Part of each electrical connection may be provided in an associated one of sub-assembly enclosures 215.

It is understood that the vertical mezzanine cards 214a discussed below in connection with FIGS. 6-8 may similarly be oriented at angle A1 in the range noted above in connection with mezzanine card 214. Similarly, vertical line card 212 may also be oriented at angle A2 in the range noted above. Angles A1 and A2 are shown in FIGS. 6-8. In addition, mezzanine cards 214b may also be oriented at a third angle in the range noted above and which may be the same or different than either angle A1 or A2.

FIG. 4 is provided as an example. Other examples may differ from what is described with regard to FIG. 4, such as in the number of components shown therein.

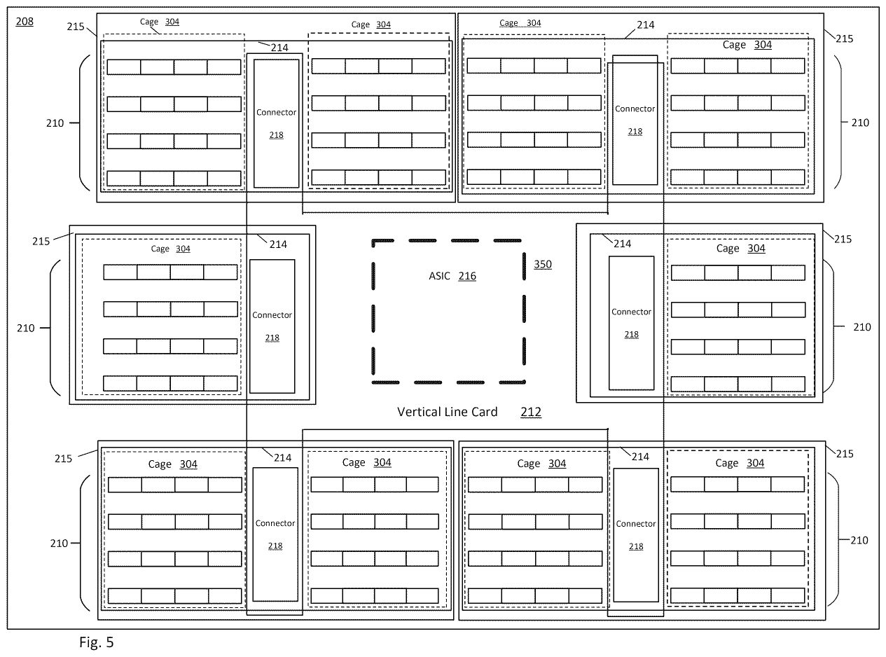

FIG. 5 shows a front view of a switch consistent with a further aspect of the present disclosure. Namely, the example shown in FIG. 5 is similar to that shown in FIG. 3A. In FIG. 5, however, vertical mezzanine cards 214 are shown overlapping cages 304 entirely when viewed from the front of housing 202. In FIG. 3A, however, mezzanine cards 215 partly overlap cages 304 when viewed from the same perspective. Otherwise, both FIGS. 3Aand 5 show mezzanine cards 214 not overlapping ASIC 216. It is understood that greater or fewer module slots can be supported than that shown in FIG. 5.

FIG. 6A shows a cross-sectional or side view of an example of an arrangement of components within the switch shown in FIG. 5. The components are similar to those shown in FIG. 4. For example, heat transfer elements 422 and receptacle connectors 424 are shown in both FIG. 4 and FIG. 6A. In addition, FIG. 6A shows first vertical mezzanine card 214a similar to mezzanine card 214 discussed above in connection with FIG. 4. In FIG. 6A, however, a second vertical mezzanine card 214b is provided. Moreover, connectors 471 are provided that connect to cables 459. Connectors 471 are provided on one side of vertical mezzanine card 214b and the receptacle connectors that connect to modules 204 are provided on the other (opposite) side of vertical mezzanine card 214b. Here, conductors are included or embedded in second mezzanine card 214b to electrically connect connectors 471 to connectors 421 and the modules. Thus, in FIG. 6 electrical signals are transmitted from cables 459 to connectors 424 via connectors 471 and the embedded conductors in second mezzanine card 214b. In one example, power and control signals are provided by vertical mezzanine cards 814b.

It is noted that in each of the examples disclosed herein, electrical signal flow from modules 204 to ASIC 216 is in the reverse direction as that described above, but otherwise such signal flow is through the components noted above that carry electrical signal from ASIC 216 to modules 204.

FIG. 6B shows an example of an arrangement of components similar to that shown in FIG. 6a. In FIG. 6b, however, sub-assembly enclosures 215 do not include cages 304. Further, in the example shown in FIG. 6B, each of connectors 471 includes a two-piece connector.

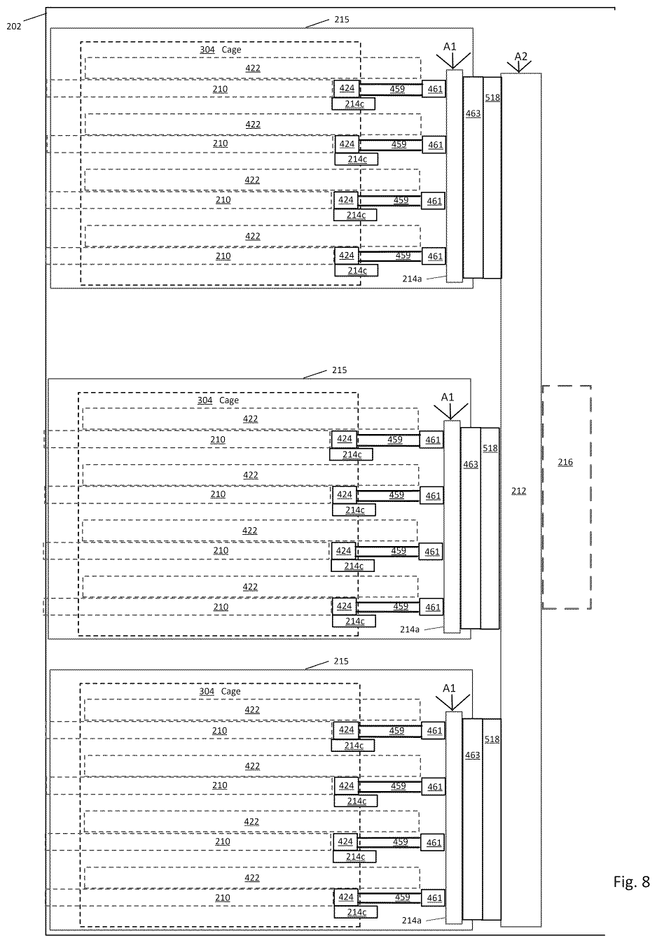

Consistent with a further aspect of the present disclosure, part of each electrical connection between connectors 424 and line card 212 in the examples disclosed herein, such as in each of the FIGS. 4, 6a, 6b, 7, and 8 may be included in a sub-assembly enclosure. Namely, in one example shown in FIG. 6b, each sub-assembly enclosure 215 may include electrical connections comprising a corresponding group of connectors 471, group of cable bundles 459, group of connectors 461, a respective one of mezzanine cards 214, and connector 463. Further, in the example shown in FIG. 6b, mezzanine cards 214b, cages 304, and connectors 424 are provided outside each sub-assembly enclosure 215. In the example shown in FIG. 4, each group of connectors 424 associated with a corresponding mode cage 304 are provided, along with the cage in a respective sub-assembly enclosure 215, and, in the examples shown in FIGS. 6a, 7, and 8, each sub-assembly enclosure further includes mezzanine cards 214 b (FIGS. 6 a and 7) or mezzanine card 214c (FIG. 8). Thus, in a further example, each sub-assembly enclosure may include one or more of connectors 424, mezzanine cards 214a, 214b, and 214c, connectors 471, cable bundles 459, connectors 461, and connector 463, as well as part of electrical connections including each of these components or elements.

FIG. 7 shows a cross-section or side view of another example of switch 104. The example shown in FIG. 7 is similar to that shown in FIG. 6. In FIG. 7, however, connectors 471 are omitted and cable 459 are connected to connectors 424 by way of conductors included in second vertical mezzanine cards 214b. In a further example, a separate direct connection is provided to second vertical mezzanine cards 214b to supply power and control signals.

FIG. 8 shows a cross-section or side view of another example of switch 104. The example shown in FIG. 8 is similar to that shown in FIG. 4. In FIG. 8, however, connectors 424 are provided on horizontal mezzanine cards 214c, which, in one example, extend parallel to bottom 206 of housing 202. In a further example, there is a direct connection for power and control to horizontal mezzanine cards 214c.

The foregoing disclosure provides illustration and description but is not intended to be exhaustive or to limit the implementations to the precise forms disclosed. Modifications may be made in light of the above disclosure or may be acquired from practice of the implementations.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

1. An apparatus, comprising:
a housing having a front panel, a top and a bottom;
a plurality of first cards, each of which is provided vertically in the housing, such that each of the plurality of first cards is oriented at a first angle relative to the front panel, the first angle is in a range from −60° to 60°;
a plurality of module cages, each of which being operable to receive a plurality of interface modules;
a plurality of sub-assembly enclosures;
a plurality of first connectors, each of which being coupled to a respective one of the plurality of interface modules, when the plurality of interface modules is provided in the plurality of cages;
a plurality of cable bundles;
a plurality of second connectors;
a plurality of third connectors;
an electrical connection extending from one of the plurality of first connectors to one of the plurality of third connectors, the electrical connection including one of the plurality of cable bundles, one of the plurality of second connectors, and one of the plurality of third connectors, one of the plurality of sub-assembly enclosures including at least a portion of the electrical connection; and
a second card coupled to said one of the plurality of third connectors, the second card being provided vertically in the housing, such that the second card is oriented at a second angle relative to the front panel, the second angle is in a range of −60° to 60°, the second card including a processor.

2. An apparatus in accordance with claim 1, wherein the plurality of sub-assembly enclosures is arranged to be non-overlapping with the processor when viewed from the front panel, and each of the plurality of first cards partially overlaps a corresponding one of the plurality of module cages when viewed from the front panel.

3. An apparatus in accordance with claim 1, wherein the plurality of sub-assembly enclosures is arranged to be overlapping with the processor when viewed from the front panel.

4. An apparatus in accordance with claim 1, wherein the plurality of sub-assembly enclosures is arranged to be non-overlapping with the processor when viewed from the front panel, and each of the plurality of first cards entirely overlaps a corresponding one of the plurality of module cages when viewed from the front panel.

5. An apparatus in accordance with claim 1, further including groups of fourth connectors and a plurality of third cards, a first side of each of the plurality of third cards facing the front panel of the chassis and a second side of each of the plurality of third cards facing the back of the chassis, each of the groups of fourth connectors being provided on the second side of each of a respective one of the plurality of third cards and connecting to respective groups of the plurality of cable bundles.

6. An apparatus in accordance with claim 5, wherein each of the plurality of third cards is provided vertically in the housing, such that each of the plurality of third cards is oriented at a second angle relative to the front panel, the second angle is in a range from −60° to 60°.

7. An apparatus in accordance with claim 5, wherein each of the plurality of third cards is oriented parallel to the bottom of the housing.

8. An apparatus in accordance with claim 5, wherein each of the plurality of sub-assembly enclosures includes at least one of: a respective one of the plurality of first cards, a respective one of the plurality of the plurality of second cards, a respective one of the plurality of module cages, a respective one of the plurality of first connectors, a respective one of the plurality of cable bundles, and a respective one of the plurality of second connectors.

9. An apparatus in accordance with claim 1, wherein said each of the plurality of sub-assembly enclosures includes a respective one of the plurality of module cages.

10. An apparatus in accordance with claim 1, wherein said each of the plurality of sub-assembly enclosures includes a respective one of the plurality of first connectors.

11. An apparatus in accordance with claim 1, wherein said each of the plurality of sub-assembly enclosures includes a respective one of the plurality of cable bundles.

12. An apparatus in accordance with claim 1, wherein said each of the plurality of sub-assembly enclosures includes a respective one of the plurality of second connectors.

13. An apparatus in accordance with claim 1, wherein said each of the plurality of sub-assembly enclosures includes a respective one of the plurality of first connectors, a respective one of the plurality of cable bundles, and a respective one of the plurality of second connectors.

14. An apparatus in accordance with claim 5, wherein each of the plurality of sub-assembly enclosures includes a respective one of the groups of fourth connectors, a respective one of the plurality of cable bundles, and a respective one of the plurality of second connectors, each of the plurality third cards, and each of the plurality of module cages being provided outside of each of the plurality of sub-assembly enclosures.

15. An apparatus in accordance with claim 1, further including a plurality of third cards, each of the plurality of third cards being attached to groups of the plurality of first connectors, groups of the plurality of cable bundles being associated with the groups of the plurality of first connectors, such that each group of the plurality of first connectors connects to a corresponding group of the plurality of cable bundles through a corresponding one of the plurality of third cards.

16. An apparatus in accordance with claim 1, wherein each of the plurality of first connectors, is operable to electrically connect to a respective one of a plurality of interface modules, when each of the plurality of interface modules is provided in a corresponding one of the plurality of module cages.

17. An apparatus in accordance with claim 12, wherein the plurality of interface modules being operable to transmit a first plurality of optical signals and receive a second plurality of optical signals.

18. An apparatus in accordance with claim 1, further including a plurality of heat transfer elements being operable to transfer heat away from the plurality of interface modules when each of the plurality of interface modules is provided in a respective one of the plurality of module cages.

19-21. (canceled)

22. An apparatus in accordance with claim 12, wherein the plurality of interface modules is operable to transmit a first plurality of electrical signals and receive a second plurality of electrical signals.

23-27. (canceled)

28. An apparatus in accordance with claim 1, wherein each of the plurality of interface modules is a pluggable module.

29-30. (canceled)

31. An apparatus, comprising:
a housing having a front panel, a top and a bottom;
a plurality of module cages;
a plurality of first connectors, each of which being operable to electrically connect to a respective one of a plurality of interface modules when the plurality of interface modules is provided in one of the plurality of module cages;
a plurality of first cards provided in the housing adjacent the front panel of the housing, such that each of the plurality of first cards is oriented at a first angle relative to the front panel, the first angle is in a range from −60° to 60°, the plurality of first connectors being provided on a first side of one of the plurality of first cards;
a plurality of second connectors provided on a second side of said one of the plurality of first cards;
a plurality of second cards being provided vertically in the housing, such that each of the plurality of second cards is oriented at a second angle relative to the front panel, the second angle is in a range from −60° to 60, each of the plurality of second cards being spaced from the plurality of first cards;
a plurality of third connectors provided on a first side of one of the plurality of second cards;
a plurality of cable bundles extending between the plurality of second connectors and the plurality of third connectors;
a fourth connector;
a third card, the fourth connector provided between a second side of said one of the plurality of second cards and the third card, the plurality of third connectors being operable to electrically connect said one of the plurality of first cards to the third card via the plurality of cable bundles and the plurality of second connectors, the third card being provided vertically in the housing, such that the third card is oriented at a third angle relative to the front panel, the third angle is in a range of −60° to 60°, the third card including a processor; and
a plurality of sub-assembly enclosures, the first plurality of connectors, the second plurality of connectors, the third plurality of connectors, said one of the plurality of first cards, and said one of the plurality of second cards being provided in one of the plurality of sub-assembly enclosures,
wherein the plurality of sub-assembly enclosures is arranged to be non-overlapping with the processor when viewed from the front panel.

32. An apparatus, comprising:
a housing having a front panel, a top and a bottom;
a plurality of module cages;
a plurality of first connectors, each of which being operable to electrically connect to a respective one of a plurality of interface modules when the plurality of interface modules is provided in one of the plurality of module cages;
a plurality of first cards provided in the housing adjacent the front panel of the housing, such that each of the plurality of first cards is oriented at a first angle relative to the front panel, the first angle is in a range from −60° to 60°, the plurality of first connectors being provided on a first side of one of the plurality of first cards, said one of the plurality of first cards having conductors extending from the first side to a second side of said one of the plurality of first cards;
a plurality of second cards being provided vertically in the housing, such that each of the plurality of second cards is oriented at a second angle relative to the front panel, the second angle is in a range from −60° to 60, each of the plurality of second cards being spaced from the plurality of first cards;
a plurality of second connectors provided on a first side of one of the plurality of second cards;
a plurality of cable bundles extending between the plurality of conductors of said one of the plurality of first cards and the plurality of second connectors;
a third connector;
a third card, the third connector being provided between a second side of said one of the plurality of second cards and the third card, the plurality of second connectors being electrically connected to said one of the plurality of first cards to the third card via the plurality of conductors of said one of the plurality of second cards and the plurality of fiber bundles, the third card being provided vertically in the housing, such that the third card is oriented at a third angle relative to the front panel, the third angle is in a range of −60° to 60°, the third card including a processor; and
a plurality of sub-assembly enclosures, the first plurality of connectors, the second plurality of connectors, the third plurality of connectors, said one of the plurality of first cards, and said one of the plurality of second cards being provided in one of the plurality of sub-assembly enclosures,
wherein the plurality of sub-assembly enclosures is arranged to be non-overlapping with the processor when viewed from the front panel.

36. (canceled)
